(19) United States
(12) Patent Application Publication
(10) Pub. No.: US 2024/0074192 A1
(43) Pub. Date: Feb. 29, 2024

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Seung Yoon Kim, Suwon-si (KR); Byoung Jae Park, Suwon-si (KR); Jae-Hwang Sim, Suwon-si (KR); Jongseon Ahn, Suwon-si (KR); Young-Ho Lee, Suwon-si (KR)

(73) Assignee: SAMSUNG ELECTRONICS CO., LTD., Suwon-si (KR)

(21) Appl. No.: 18/202,019

(22) Filed: May 25, 2023

(30) Foreign Application Priority Data
Aug. 23, 2022 (KR) 10-2022-0105426

(51) Int. Cl. H10B 43/27; H01L 23/522; H01L 23/528; H01L 25/065; H10B 41/10; H10B 41/27; H10B 41/35; H10B 41/40; H10B 43/10; H10B 43/35; H10B 43/40; H10B 80/00

(52) U.S. Cl. CPC H10B 43/27; H01L 23/5226; H01L 23/5283; H01L 25/0652; H10B 41/10; H10B 41/27; H10B 41/35; H10B 41/40; H10B 43/10; H10B 43/35; H10B 43/40; H10B 80/00; H01L 2225/06524

(57) ABSTRACT

A three-dimensional semiconductor device includes: a source structure including a cell region and an extension region; a gate stacking structure disposed on the source structure, the gate stacking structure including insulating patterns and conductive patterns, which are alternately stacked on each other; an insulating structure disposed on the gate stacking structure, the insulating structure including a plurality of insulating layers; a memory channel structure penetrating the gate stacking structure and electrically connected to the cell region; a separation structure penetrating the gate stacking structure and extending from the cell region to the extension region; and a penetration plug penetrating the gate stacking structure and the extension region, wherein the penetration plug includes: a first plug portion penetrating the gate stacking structure; and a second plug portion on the first plug portion, wherein the separation structure includes: a first separation portion penetrating the gate stacking structure; and a second separation portion on the first separation portion, and wherein a top surface of the first plug portion and a top surface of the first separation portion are at a substantially same level.

### CROSS-REFERENCE TO RELATED APPLICATION

This application claims priority under 35 U.S.C. § 119 to Korean Patent Application No. 10-2022-0105426, filed on Aug. 23, 2022, in the Korean Intellectual Property Office, the contents of which are incorporated by reference herein in their entirety.

### BACKGROUND

The present disclosure relates to a semiconductor device and an electronic system including the same, and in particular, to a three-dimensional semiconductor memory device with improved reliability and increased integration density and an electronic system including the same.

A semiconductor device capable of storing a large amount of data is needed as a data storage of an electronic system. Further, there is a need to increase the data storage capacity of the semiconductor device. For example, there is a need for semiconductor devices, in which memory cells are three-dimensionally arranged.

### SUMMARY

One or more example embodiments provide a highly-integrated and highly-reliable three-dimensional semiconductor memory device and an electronic system including the same.

According to an aspect of an example embodiment, a three-dimensional semiconductor device includes: a source structure including a cell region and an extension region; a gate stacking structure disposed on the source structure, the gate stacking structure including insulating patterns and conductive patterns, which are alternately stacked on each other; an insulating structure disposed on the gate stacking structure, the insulating structure including a plurality of insulating layers; a memory channel structure penetrating the gate stacking structure and electrically connected to the cell region; a separation structure penetrating the gate stacking structure and extending from the cell region to the extension region; and a penetration plug penetrating the gate stacking structure and the extension region, wherein the penetration plug includes: a first plug portion penetrating the gate stacking structure; and a second plug portion on the first plug portion, wherein the separation structure includes: a first separation portion penetrating the gate stacking structure; and a second separation portion on the first separation portion, and wherein a top surface of the first plug portion and a top surface of the first separation portion are at a substantially same level.

According to an aspect of an example embodiment, a three-dimensional semiconductor device includes: a source structure including a cell region and an extension region; a gate stacking structure disposed on the source structure, the gate stacking structure including insulating patterns and conductive patterns, which are alternately stacked on each other; an insulating structure disposed on the gate stacking structure, the insulating structure including a plurality of insulating layers; a memory channel structure penetrating the gate stacking structure and electrically connected to the cell region of the source structure; a supporting structure penetrating the gate stacking structure and connected to the extension region; and a penetration plug penetrating the gate stacking structure and the extension region, wherein the penetration plug includes: a first plug portion penetrating the gate stacking structure; and a second plug portion on the first plug portion, wherein the supporting structure includes: a first supporting portion; a second supporting portion on the first supporting portion; a third supporting portion on the second supporting portion; and a fourth supporting portion on the third supporting portion, and wherein a top surface of the third supporting portion and a top surface of the memory channel structure are at a substantially same level.

According to an aspect of an example embodiment, an electronic system includes: a substrate; a semiconductor device on the substrate; and a controller provided on the substrate and electrically connected to the semiconductor device, wherein the semiconductor device includes: a peripheral circuit structure including a transistor; a source structure on the peripheral circuit structure, the source structure including a cell region and an extension region; a gate stacking structure disposed on the source structure, the gate stacking structure including insulating patterns and conductive patterns, which are alternately stacked on each other; an insulating structure disposed on the gate stacking structure, the insulating structure including a plurality of insulating layers; a memory channel structure penetrating the gate stacking structure and electrically connected to the cell region; a separation structure penetrating the gate stacking structure and extending from the cell region to the extension region; and a penetration plug penetrating the gate stacking structure and the extension region, wherein the penetration plug includes: a first plug portion penetrating the gate stacking structure; and a second plug portion on the first plug portion, wherein the separation structure includes: a first separation portion penetrating the gate stacking structure; and a second separation portion on the first separation portion, and a top surface of the first plug portion and a top surface of the first separation portion are at a substantially same level.

### BRIEF DESCRIPTION OF THE DRAWINGS

The above and other aspects and features will be more apparent from the following description of one or more example embodiments taken in conjunction with the accompanying drawings, in which:

FIG. 1 is a diagram schematically illustrating an electronic system including a semiconductor device according to one or more example embodiments;

FIG. 2 is a perspective view schematically illustrating an electronic system including a semiconductor device according to one or more example embodiments;

FIGS. 3 and 4 are sectional views schematically illustrating semiconductor packages according to one or more example embodiments;

FIG. 5A is a plan view illustrating a semiconductor device according to one or more example embodiments;

FIG. 5B is a sectional view taken along a line A-A′ of FIG. 5A, according to one or more example embodiments;

FIG. 5C is a sectional view taken along a line B-B′ of FIG. 5A, according to one or more example embodiments; and

FIGS. 6A, 6B, 7A, 7B, 8A, 8B, 9A, 9B, 10A, 10B, 11A, 11B, 12A, 12B, 13A, 13B, 14A, and 14B are sectional views illustrating a method of fabricating a semiconductor device, according to one or more example embodiments.

### DETAILED DESCRIPTION

One or more example embodiments will be described more fully with reference to the accompanying drawings, in which one or more example embodiments are shown. The same reference numerals are used for the same components in the drawings, and duplicate descriptions thereof are omitted.

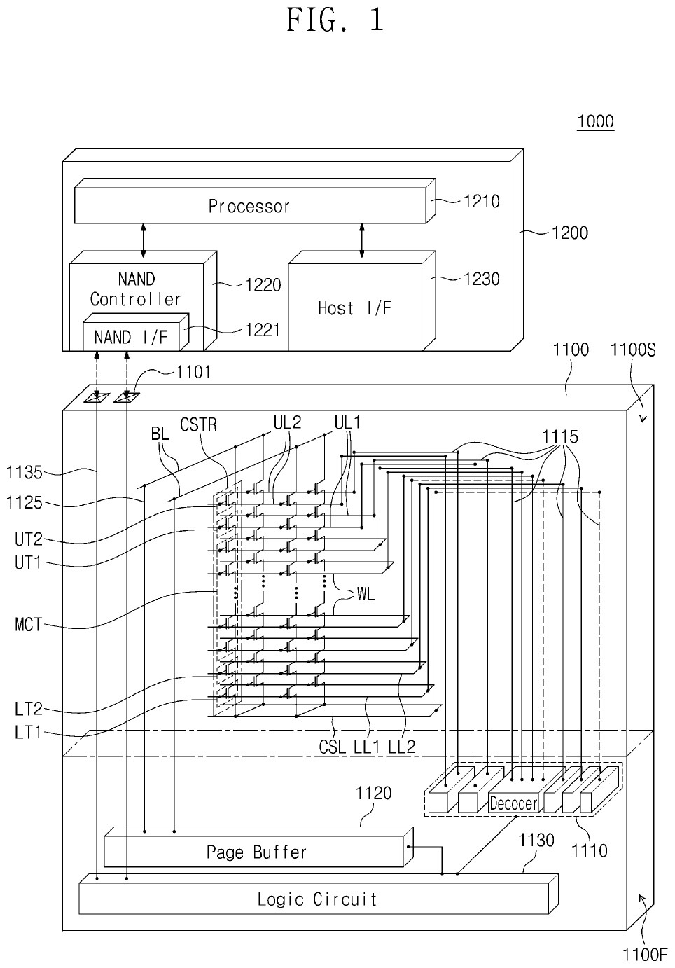

FIG. 1 is a diagram schematically illustrating an electronic system including a semiconductor device according to one or more example embodiments.

Referring to one or more example embodiments shown in FIG. 1, an electronic system 1000 according to one or more example embodiments may include a semiconductor device 1100 and a controller 1200 electrically connected to the semiconductor device 1100. The electronic system 1000 may be a storage device including one or more semiconductor devices 1100 or an electronic device including such a storage device. For example, the electronic system 1000 may be, but is not limited to, a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In one or more example embodiments, the first structure 1100F may be disposed beside the second structure 1100S. The first structure 1100F may be a peripheral circuit structure including a decoder circuit 1110, a page buffer circuit 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to one or more example embodiments.

In one or more example embodiments, the upper transistors UT1 and UT2 may include at least one string selection transistor, and the lower transistors LT1 and LT2 may include at least one ground selection transistor. The gate lower lines LL1 and LL2 may be respectively configured as gate electrodes of the lower transistors LT1 and LT2. The word lines WL may be respectively configured as gate electrodes of the memory cell transistors MCT, and the gate upper lines UL1 and UL2 may be respectively configured as gate electrodes of the upper transistors UT1 and UT2.

In one or more example embodiments, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used for an erase operation of erasing data, which are stored in the memory cell transistors MCT, using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F into the second structure 1100S. The bit lines BL may be electrically connected to the page buffer circuit 1120 through second connection lines 1125, which extend from the first structure 1100F to the second structure 1100S.

In the first structure 1100F, the decoder circuit 1110 and the page buffer circuit 1120 may be configured to perform a control operation on at least one selected from the memory cell transistors MCT. The decoder circuit 1110 and the page buffer circuit 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which extends from the first structure 1100F to the second structure 1100S.

The controller 1200 may include a processor 1210, a NAND controller 1220, and a host interface 1230. In one or more example embodiments, the electronic system 1000 may include a plurality of semiconductor devices 1100, and in this case, the controller 1200 may control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and receive control commands, which are used to control the semiconductor device 1100, and data, which will be written in or read from the memory cell transistors MCT of the semiconductor device 1100. The host interface 1230 may be configured to allow for communication between the electronic system 1000 and an external host. When a control command is received from the external host through the host interface 1230, the processor 1210 may control the semiconductor device 1100 in response to the control command.

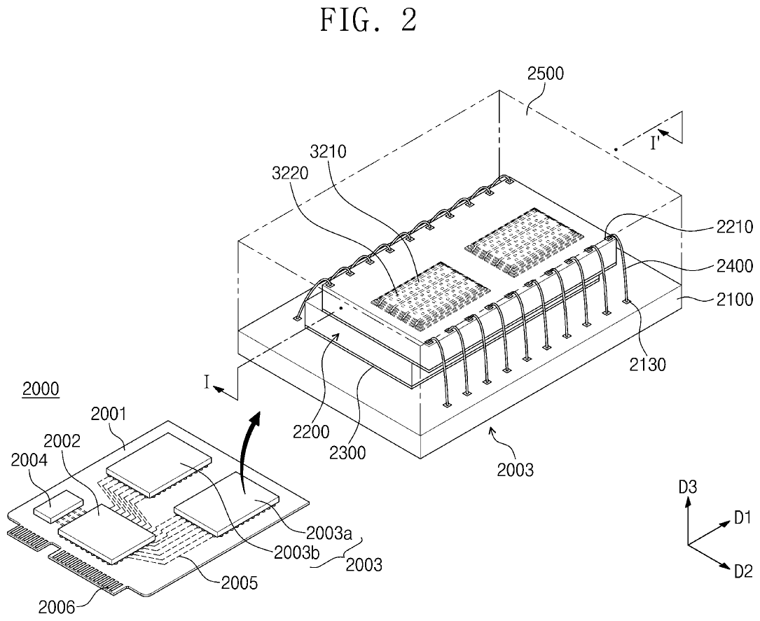

FIG. 2 is a perspective view schematically illustrating an electronic system including a semiconductor device according to one or more example embodiments.

Referring to one or more example embodiments shown in FIG. 2, an electronic system 2000 according to one or more example embodiments may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 by interconnection patterns 2005, which are formed in the main substrate 2001.

The main substrate 2001 may include a connector 2006, which includes a plurality of pins that may couple to an external host. In the connector 2006, the number and arrangement of the pins may be changed depending on a communication interface between the electronic system 2000 and the external host. In one or more example embodiments, the electronic system 2000 may communicate with the external host, in accordance with one of interfaces, including, but not limited to, universal serial bus (USB), peripheral component interconnect express (PCI-Express), serial advanced technology attachment (SATA), universal flash storage (UFS) M-Phy, or the like. In one or more example embodiments, the electronic system 2000 may be driven by a power, which is supplied from the external host through the connector 2006. The electronic system 2000 may further include a power management integrated circuit (PMIC) that is configured to distribute a power, which is supplied from the external host, to the controller 2002 and to the semiconductor package 2003.

The controller 2002 may be configured to control a writing or a reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and an external host. In one or more example embodiments, the DRAM 2004 in the electronic system 2000 may serve as a cache memory and may be used as a storage space, which is configured to store data temporarily during a control operation on the semiconductor package 2003. In one or more example embodiments where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include an input/output pad 2210. The input/output pad 2210 may correspond to the input/output pad 1101 of FIG. 1. Each of the semiconductor chips 2200 may include gate stacks 3210 and vertical structures 3220. Each of the semiconductor chips 2200 may include a semiconductor device, which will be described below, according to one or more example embodiments.

In one or more example embodiments, the connection structure 2400 may be a bonding wire, which is provided to electrically connect the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively, according to one or more example embodiments, in each of the first and second semiconductor packages 2003a and 2003b, the semiconductor chips 2200 may be electrically connected to each other by a connection structure including through-silicon vias (TSVs), rather than the connection structure 2400 provided in the form of bonding wires.

In one or more example embodiments, the controller 2002 and the semiconductor chips 2200 may be included in a single package. In one or more example embodiments, the controller 2002 and the semiconductor chips 2200 may be mounted on an additional interposer substrate different from the main substrate 2001 and may be connected to each other through interconnection lines, which are provided in the interposer substrate.

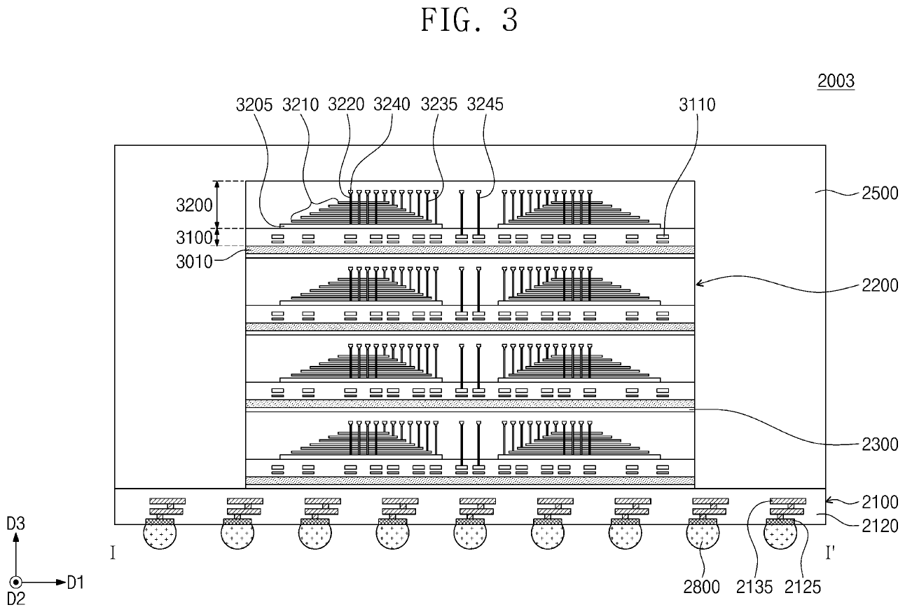

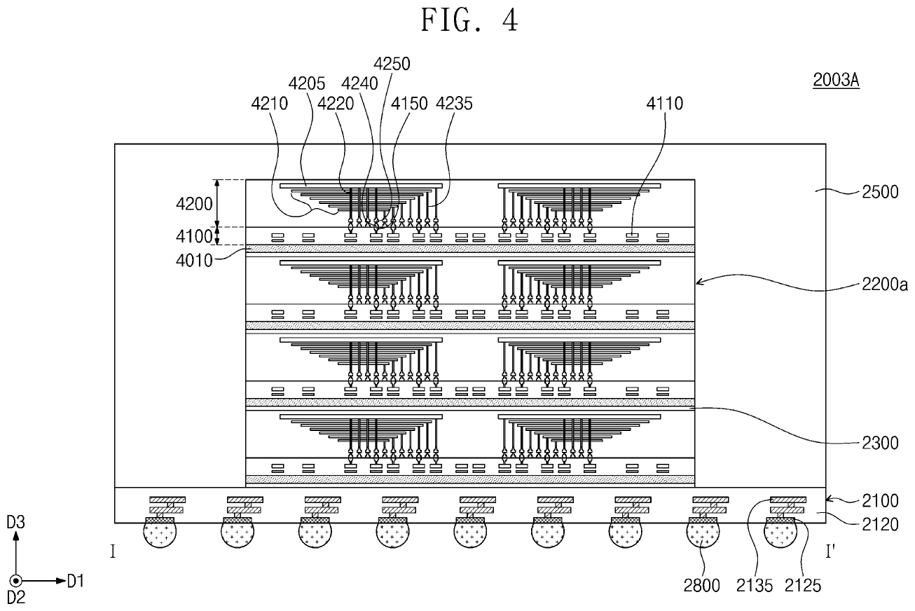

FIGS. 3 and 4 are sectional views, each of which schematically illustrates a semiconductor package according to one or more example embodiments. FIGS. 3 and 4 are sectional views taken along a line I-I′ of FIG. 2 and illustrate two different example embodiments of the semiconductor package of FIG. 2.

Referring to one or more example embodiments shown in FIG. 3, the package substrate 2100 of the semiconductor package 2003 may be a printed circuit board. The package substrate 2100 may include a package substrate body portion 2120, the package upper pads 2130 (e.g., see FIG. 2), which are disposed on a top surface of the package substrate body portion 2120, lower pads 2125, which are disposed on or exposed through a bottom surface of the package substrate body portion 2120, and internal lines 2135, which are disposed in the package substrate body portion 2120 to electrically connect the package upper pads 2130 to the lower pads 2125. The package upper pads 2130 may be electrically connected to the connection structure 2400. The lower pads 2125 may be connected to the interconnection patterns 2005 of the main substrate 2001 of the electronic system 2000 shown in FIG. 2 through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region including peripheral lines 3110. The second structure 3200 may include a source structure 3205, a stack 3210 on the source structure 3205, the vertical structures 3220 and separation structures 3230 penetrating the stack 3210, bit lines 3240 electrically connected to the vertical structures 3220, and cell contact plugs 3235 electrically connected to the word lines WL (e.g., see FIG. 1) of the stack 3210. Each of the first and second structures 3100 and 3200 and the semiconductor chips 2200 may further include separation structures to be described below.

Each of the semiconductor chips 2200 may include a penetration line 3245, which is electrically connected to the peripheral lines 3110 of the first structure 3100 and extends into the second structure 3200. The penetration line 3245 may be disposed outside the stack 3210, and in one or more example embodiments, the penetration line 3245 may be provided to further penetrate the stack 3210. Each of the semiconductor chips 2200 may further include the input/output pad 2210 (e.g., see FIG. 2), which is electrically connected to the peripheral lines 3110 of the first structure 3100.

Referring to one or more example embodiments shown in FIG. 4, in the semiconductor package 2003A, each of the semiconductor chips 2200a may include a semiconductor substrate 4010, a first structure 4100 on the semiconductor substrate 4010, and a second structure 4200, which is provided on the first structure 4100 and is bonded to the first structure 4100 in a wafer bonding manner, for instance.

The first structure 4100 may include a peripheral circuit region including a peripheral line 4110 and first junction structures 4150. The second structure 4200 may include a source structure 4205, a stack 4210 between the source structure 4205 and the first structure 4100, vertical structures 4220 and a separation structure 4230 penetrating the stack 4210, and second junction structures 4250, which are electrically and respectively connected to the vertical structures 4220 and the word lines WL (e.g., see FIG. 1) of the stack 4210. For example, the second junction structures 4250 may be electrically connected to the vertical structures 4220 and the word lines WL (e.g., see FIG. 1), respectively, through bit lines 4240 electrically connected to the vertical structures 4220 and cell contact plugs 4235 electrically connected to the word lines WL (e.g., see FIG. 1). The first junction structures 4150 of the first structure 4100 may be in contact with and bonded to the second junction structures 4250 of the second structure 4200. The bonded portions of the first junction structures 4150 and the second junction structures 4250 may be formed of, or include, but are not limited to, for example, copper (Cu).

Each of the first and second structures 4100 and 4200 and the semiconductor chips 2200a may further include a source structure according to one or more example embodiments to be described below. Each of the semiconductor chips 2200a may further include the input/output pad 2210 (e.g., see FIG. 2), which is electrically connected to the peripheral line 4110 of the first structure 4100.

The semiconductor chips 2200 of FIG. 3 and the semiconductor chips 2200a of FIG. 4 may be electrically connected to each other by the connection structure 2400, which may be provided in the form of bonding wires. However, in one or more example embodiments, semiconductor chips provided in each semiconductor package (e.g., the semiconductor chips 2200 of FIG. 3 and the semiconductor chips 2200a of FIG. 4) may be electrically connected to each other through a connection structure including through-silicon vias (TSVs).

The first structure 3100 of FIG. 3 and the first structure 4100 of FIG. 4 may correspond to a peripheral circuit structure in one or more example embodiments described below, and the second structure 3200 of FIG. 3 and the second structure 4200 of FIG. 4 may correspond to a cell array structure in one or more example embodiments described below.

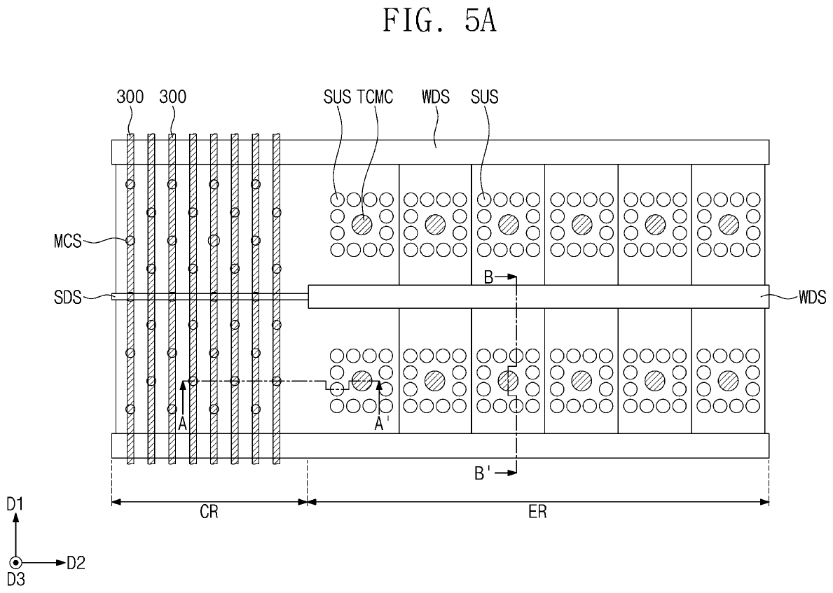

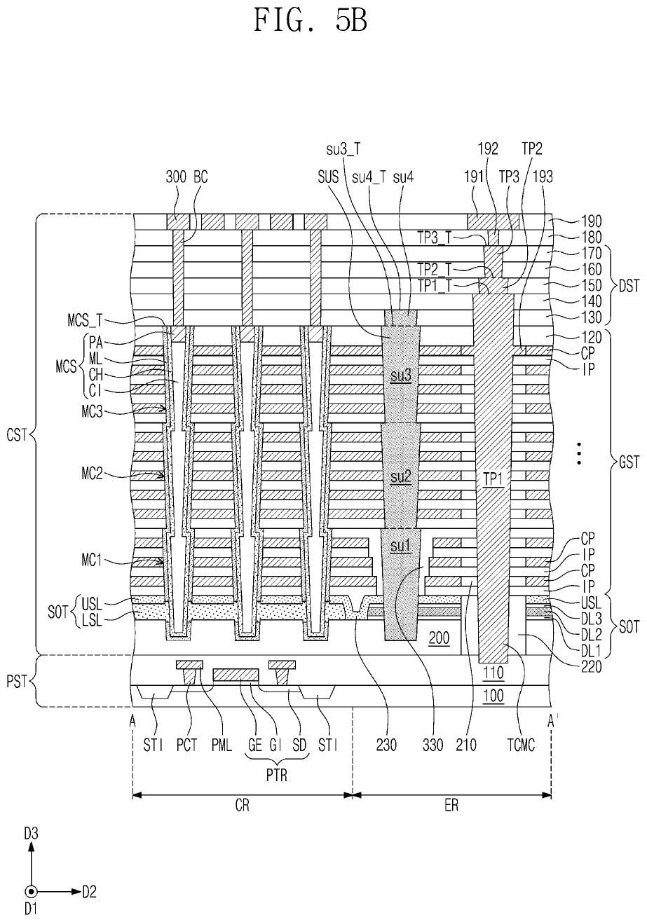

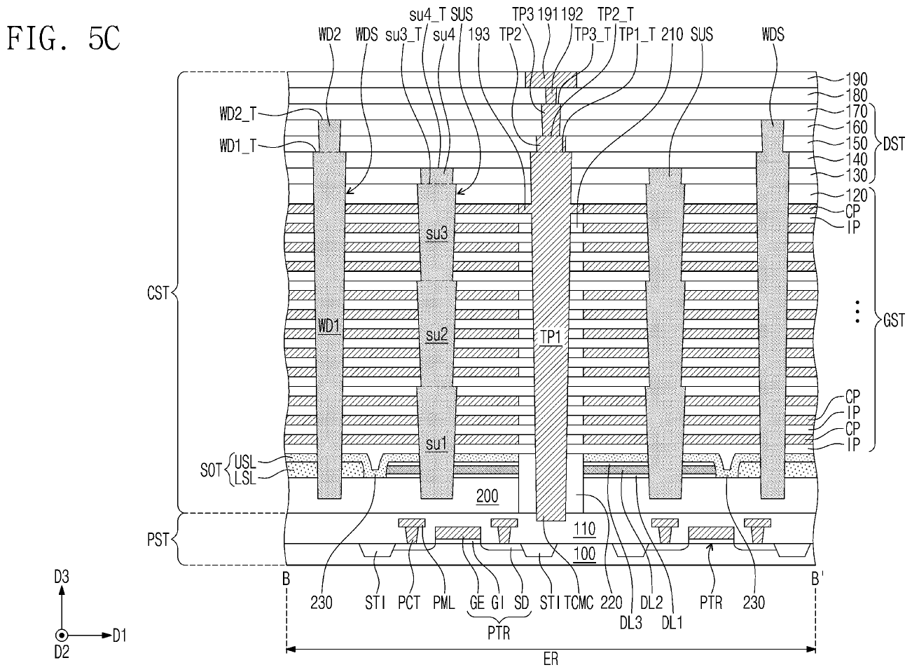

FIG. 5A is a plan view illustrating a semiconductor device according to one or more example embodiments. FIG. 5B is a sectional view taken along a line A-A′ of FIG. 5A. FIG. 5C is a sectional view taken along a line B-B′ of FIG. 5A.

Referring to one or more example embodiments shown in FIGS. 5A, 5B, and 5C a semiconductor device according to one or more example embodiments may include a peripheral circuit structure PST and a memory cell structure CST. The memory cell structure CST may be provided on the peripheral circuit structure PST.

The peripheral circuit structure PST may include a substrate 100. The substrate 100 may be a plate-shaped structure that extends parallel to a plane defined by a first direction D1 and a second direction D2. According to one or more example embodiments the first and second directions D1 and D2 may not be parallel to each other. According to one or more example embodiments, the first and second directions D1 and D2 may be orthogonal to each other. In one or more example embodiments, the substrate 100 may be a semiconductor substrate. According to one or more example embodiments, the substrate 100 may be a silicon wafer. Alternatively, according to one or more example embodiments, the substrate 100 may be a silicon-on-insulator (SOI) wafer.

The peripheral circuit structure PST may further include a peripheral insulating layer 110 covering the substrate 100. The peripheral insulating layer 110 may cover a top surface of the substrate 100. The peripheral insulating layer 110 may be formed of, or include, at least one of insulating materials. According to one or more example embodiments, the peripheral insulating layer 110 may be formed of or include an oxide material. In one or more example embodiments, the peripheral insulating layer 110 may be a multiple insulating layer including a plurality of insulating layers.

The peripheral circuit structure PST may further include a peripheral transistor PTR. The peripheral transistor PTR may be provided between the substrate 100 and the peripheral insulating layer 110. The peripheral transistor PTR may include source/drain regions SD, a gate electrode GE, and a gate insulating layer GI. The gate electrode GE and the gate insulating layer GI may be provided between the source/drain regions SD. The gate electrode GE may be spaced apart from the substrate 100 by the gate insulating layer GI. The source/drain regions SD may be formed by doping the substrate 100 with impurities. The gate electrode GE may be formed of, or include, at least one of conductive materials. The gate insulating layer GI may be formed of, or include, at least one of insulating materials.

The peripheral circuit structure PST may further include device isolation layers STI. The device isolation layers STI may be provided in the substrate 100. The device isolation layers STI may be disposed between the peripheral transistors PTR to electrically separate the peripheral transistors PTR from each other. The device isolation layer STI may be formed of, or include, at least one of insulating materials.

The peripheral circuit structure PST may further include peripheral contacts PCT and peripheral lines PML. The peripheral contacts PCT may be connected to the peripheral transistor PTR, and the peripheral lines PML may be connected to the peripheral contacts PCT. The peripheral contacts PCT and the peripheral lines PML may be provided in the peripheral insulating layer 110. The peripheral contacts PCT and the peripheral lines PML may be formed of, or include, at least one of conductive materials.

The memory cell structure CST may include a semiconductor layer 200, a source structure SOT, a gate stacking structure GST, memory channel structures MCS, supporting structures SUS, penetration plugs TCMC, an insulating structure DST, and separation structures WDS.

The semiconductor layer 200 may be disposed on the peripheral insulating layer 110 of the peripheral circuit structure PST. The semiconductor layer 200 may be formed of, or include, a doped or extrinsic semiconductor material and/or an undoped or intrinsic semiconductor material. For example, the semiconductor layer 200 may be formed of, or include, but is not limited to, at least one of silicon (Si), germanium (Ge), silicon germanium (SiGe), gallium arsenic (GaAs), indium gallium arsenic (InGaAs), or aluminum gallium arsenic (AlGaAs).

The source structure SOT may include a cell region CR and an extension region ER. The cell and extension regions CR and ER of the source structure SOT may be two regions, which are separately defined on a plan view parallel to the first and second directions D1 and D2.

The source structure SOT may be provided on the semiconductor layer 200. The source structure SOT may include a lower source layer LSL, an upper source layer USL, a first dummy layer DL1, a second dummy layer DL2, and a third dummy layer DL3. The lower source layer LSL, the upper source layer USL, the first dummy layer DL1, the second dummy layer DL2, and the third dummy layer DL3 may be provided on the semiconductor layer 200.

The lower source layer LSL may be provided on the semiconductor layer 200. The lower source layer LSL may be disposed in the cell region CR. The lower source layer LSL may be formed of, or include, at least one of conductive materials. According to one or more example embodiments, the lower source layer LSL may be formed of, or include, but is not limited to, doped poly silicon.

The first dummy layer DL1, the second dummy layer DL2, and the third dummy layer DL3 may be provided on the semiconductor layer 200 sequentially in a third direction D3. The third direction D3 may not be parallel to the first and second directions D1 and D2. According to one or more example embodiments, the third direction D3 may be orthogonal to the first and second directions D1 and D2.

The first, second and third dummy layers DL1, DL2, and DL3 may be disposed in the extension region ER. The first, second and third dummy layers DL1, DL2, and DL3 may be disposed at the same level as the lower source layer LSL. The first, second and third dummy layers DL1, DL2, and DL3 may be formed of, or include, at least one of insulating materials. In one or more example embodiments, the first and third dummy layers DL1 and DL3 may be formed of, or include, the same insulating material, and the second dummy layer DL2 may be formed of, or include, an insulating material different from the first and third dummy layers DL1 and DL3. According to one or more example embodiments, the second dummy layer DL2 may be formed of, or include, silicon nitride, and the first and third dummy layers DL1 and DL3 may be formed of, or include, silicon oxide.

The upper source layer USL may cover the lower source layer LSL and the first, second and third dummy layers DL1, DL2, and DL3. The upper source layer USL may extend from the cell region CR to the extension region ER. The upper source layer USL may be formed of, or include, a semiconductor material. According to one or more example embodiments, the upper source layer USL may be formed of, or include, but is not limited to, doped or undoped poly silicon. The upper source layer USL may include a source separation portion 230. The source separation portion 230 may be placed between the cell region CR and the extension region ER. The source separation portion 230 may be placed between the supporting structure SUS and the separation structure WDS. The source separation portion 230 may be placed between the first, second and third dummy layers DL1, DL2, and DL3 and the lower source layer LSL.

The gate stacking structure GST may be provided on the source structure SOT. The gate stacking structure GST may include insulating patterns IP and conductive patterns CP, which are alternately stacked on top of each other in the third direction D3. The gate stacking structure GST may include a gate insulating layer 120, which is provided above the insulating and conductive patterns IP and CP. The insulating patterns IP may be formed of, or include, at least one of insulating materials. According to one or more example embodiments, the insulating patterns IP may be formed of, or include, an oxide material. The conductive patterns CP may be formed of, or include, at least one of conductive materials.

The gate stacking structure GST may further include a staircase insulating layer 330. The staircase insulating layer 330 may be disposed in the extension region ER. The insulating and conductive patterns IP and CP, which are disposed around the staircase insulating layer 330, may be provided to form a stepwise shape. The staircase insulating layer 330 may be provided to enclose the supporting structure SUS. A width of the staircase insulating layer 330 may increase as a distance from the source structure SOT increases. The gate stacking structure GST may be spaced apart from a first supporting portion su1 of the supporting structure SUS, described below, by the staircase insulating layer 330.

The memory channel structures MCS may be disposed in the cell region CR. The memory channel structures MCS may extend in the third direction D3 to penetrate the conductive and insulating patterns CP and IP of the gate stacking structure GST and the upper and lower source layers USL and LSL of the source structure SOT. The memory channel structures MCS may be provided to penetrate the gate stacking structure GST and may be electrically connected to the cell region CR of the source structure SOT. The memory channel structures MCS may be enclosed by the insulating and conductive patterns IP and CP of the gate stacking structure GST. The lowermost portion of the memory channel structure MCS may be disposed in the semiconductor layer 200.

Each of the memory channel structures MCS may include a core insulating layer CI, a pad PA, a channel layer CH, and a memory layer ML. The core insulating layer CI may extend in the third direction D3 to penetrate the conductive and insulating patterns CP and IP of the gate stacking structure GST and the upper and lower source layers USL and LSL of the source structure SOT. The core insulating layer CI may be formed of, or include, at least one of insulating materials. According to one or more example embodiments, the core insulating layer CI may be formed of, or include, but is not limited to, an oxide material. The pad PA may be provided on the core insulating layer CI. The pad PA may be formed of, or include, at least one of conductive materials.

The channel layer CH may be provided to enclose the core insulating layer CI and the pad PA. The channel layer CH may extend in the third direction D3 to penetrate the conductive and insulating patterns CP and IP of the gate stacking structure GST and the upper and lower source layers USL and LSL of the source structure SOT. The channel layer CH may cover side and bottom surfaces of the core insulating layer CI. The channel layer CH may be in contact with the lower source layer LSL of the source structure SOT. The memory channel structure MCS may be electrically connected to the source structure SOT. The channel layer CH of the memory channel structure MCS may be electrically connected to the lower source layer LSL of the source structure SOT. The channel layer CH may be formed of, or include, a semiconductor material. According to one or more example embodiments, the channel layer CH may be formed of, or include, but is not limited to, poly silicon.

The memory layer ML may be provided to enclose the channel layer CH. The memory layer ML may extend in the third direction D3 to penetrate the conductive and insulating patterns CP and IP of the gate stacking structure GST. The memory layer ML may be enclosed by the conductive and insulating patterns CP and IP of the gate stacking structure GST.

Each of the memory channel structures MCS may include a first channel portion MC1, a second channel portion MC2 on the first channel portion MC1, and a third channel portion MC3 on the second channel portion MC2. The third channel portion MC3 may include the pad PA. The first, second and third channel portions MC1, MC2, and MC3 may be continuously connected to form a single object without a boundary therebetween. A width of each of the first, second and third channel portions MC1, MC2, and MC3 may decrease as a vertical level decreases.

The supporting structures SUS may be disposed in the extension region ER. The supporting structures SUS may extend in the third direction D3 to penetrate the conductive and insulating patterns CP and IP of the gate stacking structure GST and the upper source layer USL and the first, second and third dummy layers DL1, DL2, and DL3 of the source structure SOT. The supporting structures SUS may be provided to penetrate the gate stacking structure GST and may be connected to the extension region ER of the source structure SOT. The supporting structures SUS may be formed of, or include, at least one of insulating materials. According to one or more example embodiments, the supporting structures SUS may be formed of, or include, but are not limited to, an oxide material.

The supporting structures SUS may include a first supporting portion su1, a second supporting portion su2 on the first supporting portion su1, a third supporting portion su3 on the second supporting portion su2, and a fourth supporting portion su4 on the third supporting portion su3. The first, second, third and fourth supporting portions su1, su2, su3, and su4 may be continuously connected to form a single object without a boundary therebetween. A width of each of the first, second, third and fourth supporting portions su1, su2, su3, and su4 may decrease as a vertical level decreases.

The supporting structures SUS may be enclosed by the conductive and insulating patterns CP and IP of the gate stacking structure GST. The lowermost portion of the supporting structure SUS may be disposed in the semiconductor layer 200.

At least one of the first, second and third supporting portions su1, su2, and su3 may be enclosed by the staircase insulating layer 330. Due to the staircase insulating layer 330, a width of the supporting structures SUS in the second direction D2 may be larger than that of the memory channel structure MCS.

A top surface of the first supporting portion su1 of the supporting structure SUS may be located at the same level as a top surface of the first channel portion MC1 of the memory channel structure MCS. A top surface of the second supporting portion su2 of the supporting structure SUS may be located at the same level as a top surface of the second channel portion MC2 of the memory channel structure MCS. A top surface su3_T of the third supporting portion su3 of the supporting structure SUS may be located at the same level as a top surface of the third channel portion MC3 of the memory channel structure MCS. The top surface su3_T of the third supporting portion su3 may be coplanar with a top surface MCS_T of the memory channel structure MCS.

The penetration plugs TCMC may be disposed in the extension region ER. The penetration plugs TCMC may extend in the third direction D3 to penetrate the conductive and insulating patterns CP and IP of the gate stacking structure GST, the upper source layer USL and the first, second and third dummy layers DL1, DL2, and DL3 of the source structure SOT, and the semiconductor layer 200. The penetration plugs TCMC may be provided to penetrate the gate stacking structure GST and the extension region ER of the source structure SOT.

Plug insulating patterns 210 may be provided between the penetration plugs TCMC and some of the conductive patterns CP of the gate stacking structure GST. Plug conductive patterns 193 may be provided between the penetration plugs TCMC and some of the conductive patterns CP of the gate stacking structure GST. A plug insulating layer 220 may be provided between the penetration plugs TCMC and the upper source layer USL, between the penetration plugs TCMC and the first, second and third dummy layers DL1, DL2, and DL3, and between the penetration plugs TCMC and the semiconductor layer 200.

The plug insulating patterns 210 and the plug insulating layer 220 may be formed of, or include, at least one of insulating materials. The plug insulating patterns 210 may prevent the penetration plugs TCMC from being electrically connected to the conductive patterns CP of the gate stacking structure GST. The penetration plugs TCMC may be electrically connected to the conductive patterns CP of the gate stacking structure GST through the plug conductive patterns 193.

The plug insulating layer 220 may prevent the penetration plugs TCMC from being directly connected to the source structure SOT. Due to the plug insulating patterns 210, the plug conductive patterns 193, and the plug insulating layer 220, the penetration plugs TCMC may be electrically connected to specific ones of the conductive patterns 193 of the gate stacking structure GST and may be electrically disconnected from the others of the conductive patterns 193. The penetration plugs TCMC may be formed of, or include, at least one of conductive materials. According to one or more example embodiments, the penetration plugs TCMC may be formed of, or include, but are not limited to, tungsten.

The penetration plugs TCMC may include a first plug portion TP1, a second plug portion TP2 on the first plug portion TP1, and a third plug portion TP3 on the second plug portion TP2. The first, second and third plug portions TP1, TP2, and TP3 may be continuously connected to form a single object without a boundary therebetween.

The first plug portion TP1 may be provided to penetrate the gate stacking structure GST and the source structure SOT. The first plug portion TP1 may be enclosed by the conductive and insulating patterns CP and IP of the gate stacking structure GST. The lowermost portion of the first plug portion TP1 may be disposed in the peripheral insulating layer 110. A width of each of the first and second plug portions TP1 and TP2 may decrease as a vertical level decreases.

In one or more example embodiments, 16 supporting structures SUS may be provided to enclose one penetration plug TCMC, when viewed in a plan view.

The separation structures WDS may extend from the cell region CR to the extension region ER. The separation structures WDS may be provided to penetrate the gate stacking structure GST and may be connected to the source structure SOT. The separation structures WDS in the cell region CR may extend in the third direction D3 to penetrate the conductive and insulating patterns CP and IP of the gate stacking structure GST and the upper and lower source layers USL and LSL of the source structure SOT. The separation structures WDS in the extension region ER may extend in the third direction D3 to penetrate the conductive and insulating patterns CP and IP of the gate stacking structure GST and the upper source layer USL and the first, second and third dummy layers DL1, DL2, and DL3 of the source structure SOT. The separation structures WDS may be formed of, or include, at least one of insulating materials. According to one or more example embodiments, the separation structures WDS may be formed of, or include, but are not limited to, an oxide material. In one or more example embodiments, the separation structure WDS may further include a conductive material. The lowermost portion of the separation structures WDS may be disposed in the semiconductor layer 200. The separation structures WDS may include a first separation portion WD1 and a second separation portion WD2 on the first separation portion WD1. The first and second separation portions WD1 and WD2 may be continuously connected to form a single object without a boundary therebetween.

The first separation portion WD1 may be provided to penetrate the gate stacking structure GST and the source structure SOT. The lowermost portion of the first separation portion WD1 may be disposed in the semiconductor layer 200. A width of each of the first and second separation portions WD1 and WD2 may decrease as a vertical level decreases. The width of the first separation portion WD1 may be larger than the width of the second separation portion WD2.

The insulating structure DST may be disposed on the gate stacking structure GST. The insulating structure DST may include a plurality of insulating layers. For example, the insulating structure DST may include a first insulating layer 130, a second insulating layer 140 on the first insulating layer 130, a third insulating layer 150 on the second insulating layer 140, a fourth insulating layer 160 on the third insulating layer 150, and a fifth insulating layer 170 on the fourth insulating layer 160. The first, second, third, fourth and fifth insulating layers 130, 140, 150, 160, and 170 may be formed of, or include, at least one of insulating materials. In one or more example embodiments, the number of the insulating layers constituting the insulating structure DST may be different from that in the illustrated example.

A contact insulating layer 180 may be disposed on the insulating structure DST. A line insulating layer 190 may be disposed on the contact insulating layer 180. The contact insulating layer 180 and the line insulating layer 190 may be formed of, or include, at least one of insulating materials. A bit line contact BC may be provided to penetrate the contact insulating layer 180 and the insulating structure DST and may be electrically connected to the memory channel structure MCS. Bit line contacts BC may be formed of, or include, at least one of conductive materials.

Bit lines 300 may be provided in the line insulating layer 190. The bit lines 300 may extend in the first direction D1. The bit lines 300 may be spaced apart from each other in the second direction D2. The bit lines 300 may be electrically connected to the memory channel structure MCS through the bit line contact BC. The bit lines 300 may be formed of, or include, at least one of conductive materials.

A plug contact 192 may be provided in the contact insulating layer 180. A plug conductive line 191 may be provided in the line insulating layer 190. The plug contact 192 may be provided to penetrate the contact insulating layer 180 and may be electrically connected to the penetration plug TCMC. The plug conductive line 191 may be electrically connected to the penetration plug TCMC through the plug contact 192. A length of the bit line contact BC may be larger than a length of the plug contact 192.

The memory cell structure CST may further include an upper separation line SDS. The upper separation line SDS may be disposed in the cell region CR. The upper separation line SDS may extend in the second direction D2. The upper separation line SDS may be provided to cut at least one of upper ones of the conductive patterns CP of the gate stacking structure GST. The upper separation line SDS may be formed of, or include, at least one of insulating materials. According to one or more example embodiments, the upper separation line SDS may be formed of, or include, but is not limited to, an oxide material.

A level of the top surface su3_T of the third supporting portion su3 of the supporting structure SUS may be equal to a level of a top surface of the gate insulating layer 120. A level of the top surface MCS_T of the memory channel structure MCS may be equal to the level of the top surface of the gate insulating layer 120. The level of the top surface MCS_T of the memory channel structure MCS may be equal to a level of a bottom surface of the first insulating layer 130 of the insulating structure DST. A level of the top surface su3_T of the third supporting portion su3 of the supporting structure SUS may be equal to the level of the bottom surface of the first insulating layer 130 of the insulating structure DST.

A top surface of the fourth supporting portion su4 of the supporting structure SUS may be placed at the same level as a bottom surface of the second insulating layer 140 of the insulating structure DST.

A top surface TP1_T of the first plug portion TP1 of the penetration plug TCMC may be coplanar with a top surface WD1_T of the first separation portion WD1 of the separation structure WDS. The top surface TP1_T of the first plug portion TP1 may be located at the same level as a top surface of the second insulating layer 140 of the insulating structure DST. The top surface WD1_T of the first separation portion WD1 may be located at the same level as the top surface of the second insulating layer 140 of the insulating structure DST.

A top surface TP2_T of the second plug portion TP2 of the penetration plug TCMC may be located at the same level as a top surface of the third insulating layer 150 of the insulating structure DST.

A top surface WD2_T of the second separation portion WD2 of the separation structure WDS may be located at the same level as a top surface of the fourth insulating layer 160 of the insulating structure DST.

A top surface TP3_T of the third plug portion TP3 of the penetration plug TCMC may be located at the same level as a level of a top surface of the fifth insulating layer 170 of the insulating structure DST.

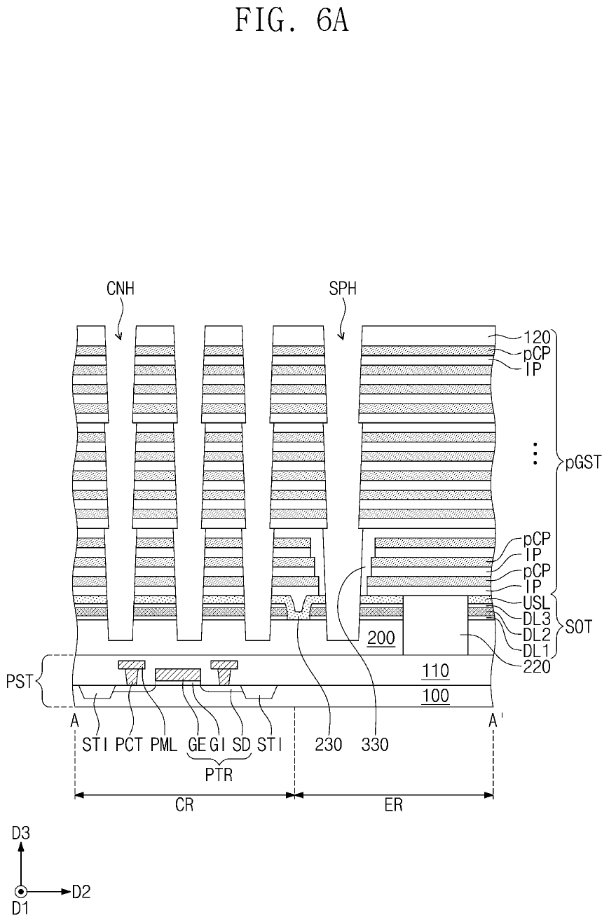

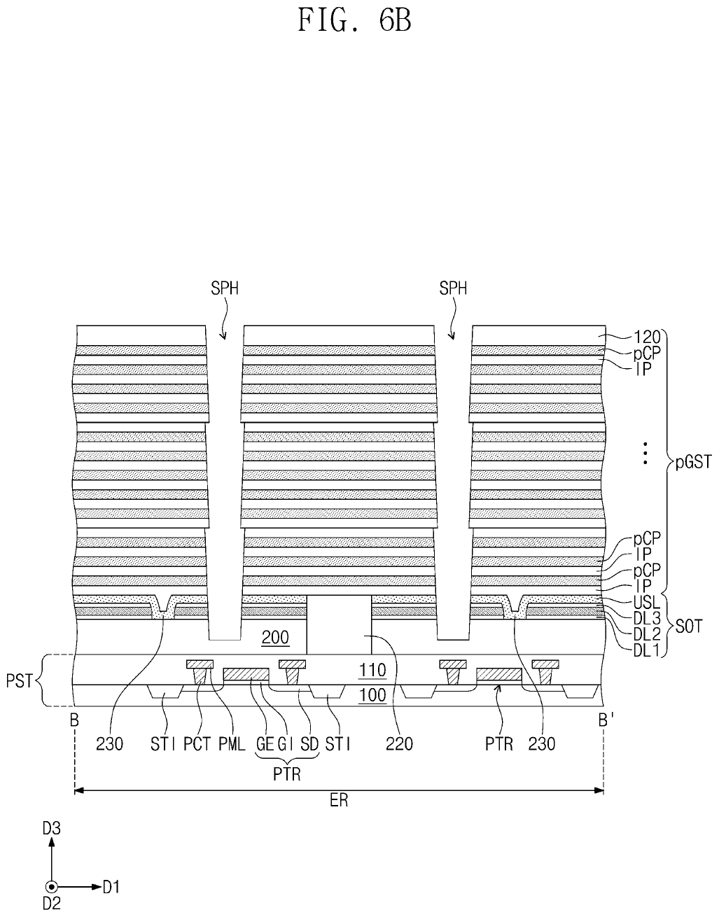

FIGS. 6A, 6B, 7A, 7B, 8A, 8B, 9A, 9B, 10A, 10B, 11A, 11B, 12A, 12B, 13A, 13B, 14A, and 14B are sectional views illustrating a method of fabricating a semiconductor device, according to one or more example embodiments.

Referring to one or more example embodiments shown in FIGS. 6A and 6B, the peripheral circuit structure PST may be formed. The formation of the peripheral circuit structure PST may include forming the peripheral transistors PTR, the device isolation layers STI, the peripheral contacts PCT, the peripheral lines PML, and the peripheral insulating layer 110 on the substrate 100. The semiconductor layer 200 may be formed on the peripheral circuit structure PST.

The source structure SOT may be formed on the semiconductor layer 200. The source structure SOT may include the first dummy layer DL1, the second dummy layer DL2, the third dummy layer DL3, and the upper source layer USL, which are sequentially stacked in the third direction D3. The first, second and third dummy layers DL1, DL2, and DL3 and the upper source layer USL may extend from the cell region CR to the extension region ER. The source separation portion 230 of the source structure SOT may be formed between the cell region CR and the extension region ER. The plug insulating layer 220 may be formed to penetrate the source structure SOT and the semiconductor layer 200. In one or more example embodiments, the plug insulating layer 220 may be formed by forming a trench penetrating the source structure SOT and the semiconductor layer 200 and filling the trench with an insulating material.

A preliminary gate stacking structure pGST, channel holes CNH, and supporting holes SPH may be formed. The channel holes CNH and the supporting holes SPH may be formed to extend in the third direction D3 and to penetrate the preliminary gate stacking structure pGST and the source structure SOT. The channel holes CNH may be formed in the cell region CR. The supporting holes SPH may be formed in the extension region ER. The channel holes CNH and the supporting holes SPH may be formed at the same time (e.g., using the same process). The channel holes CNH and the supporting holes SPH may be formed by, for example, an atomic layer etching process.

The formation of the preliminary gate stacking structure pGST may include alternately stacking first material layers and second material layers on the source structure SOT, patterning the first and second material layers to form a stepwise structure in the extension region ER, forming the staircase insulating layer 330, forming the gate insulating layer 120, and forming the channel holes CNH and the supporting holes SPH. The first material layers, which are penetrated by the channel holes CNH and the supporting holes SPH, may be defined as the insulating patterns IP. The second material layers, which are penetrated by the channel holes CNH and the supporting holes SPH, may be defined as sacrificial patterns pCP. The sacrificial patterns pCP may be formed of, or include, a material having an etch selectivity with respect to the insulating patterns IP. According to one or more example embodiments, the sacrificial patterns pCP may be formed of, or include, but are not limited to, a nitride material. In one or more example embodiments, the preliminary gate stacking structure pGST, the channel holes CNH, and the supporting holes SPH may be formed by a triple-stack forming process.

Because the staircase insulating layer 330 is formed, the supporting holes SPH may be formed to have a width larger than the channel holes CNH.

The channel holes CNH and the supporting holes SPH may be formed to expose side surfaces of the sacrificial patterns pCP, side surfaces of the insulating patterns IP, side surfaces of the upper source layer USL, side surfaces of the first, second and third dummy layers DL1, DL2, and DL3, and the semiconductor layer 200.

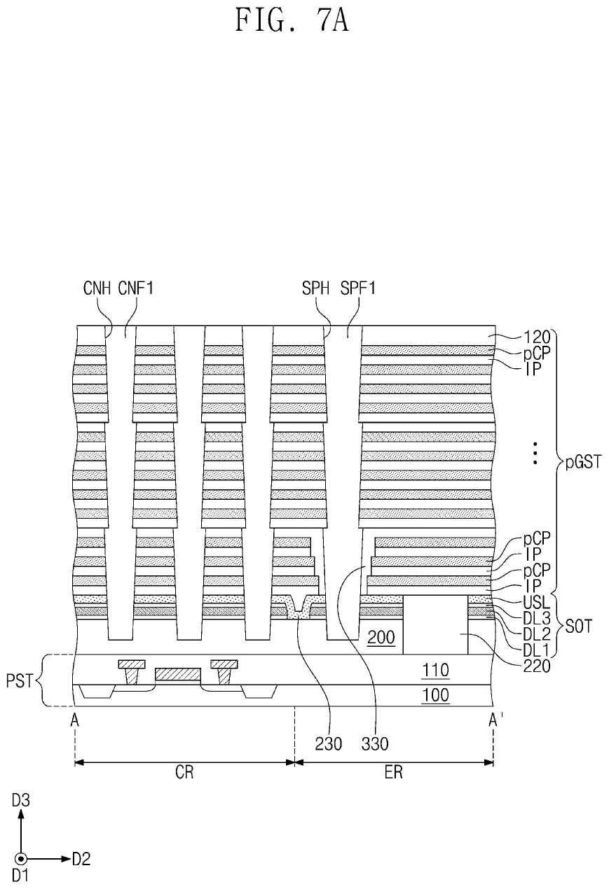

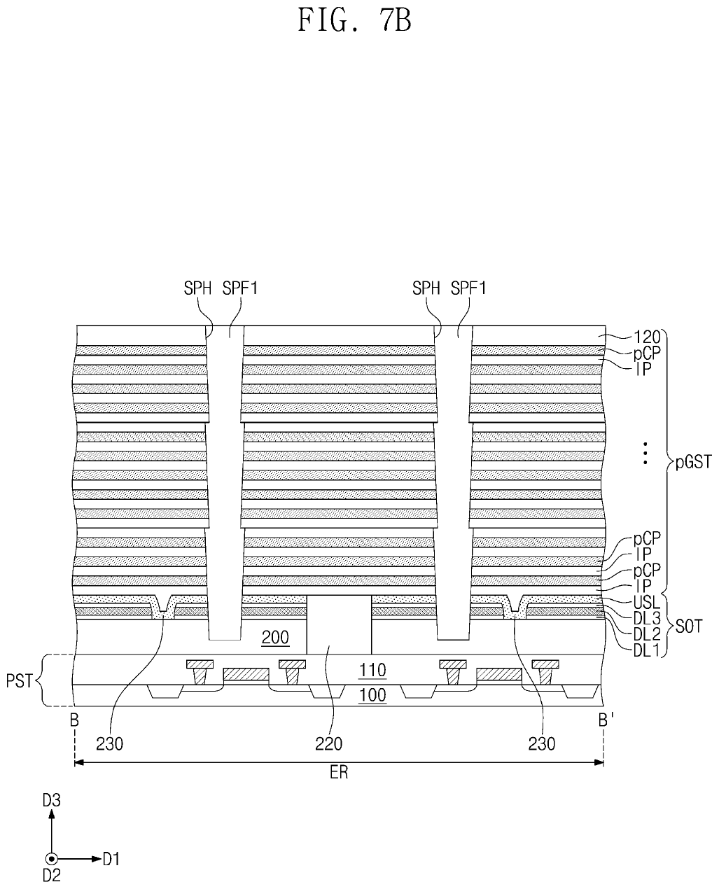

Referring to one or more example embodiments shown in FIGS. 7A and 7B, a first channel filler CNF1 and a first supporting filler SPF1 may be formed by filling the channel holes CNH and the supporting holes SPH with a first sacrificial material. In one or more example embodiments, the first sacrificial material may be carbon. The first channel filler CNF1 and the first supporting filler SPF1 may cover the side surfaces of the sacrificial patterns pCP, the side surfaces of the insulating patterns IP, the side surfaces of the upper source layer USL, the side surfaces of the first, second and third dummy layers DL1, DL2, and DL3, and the semiconductor layer 200, which are exposed through the channel holes CNH and the supporting holes SPH.

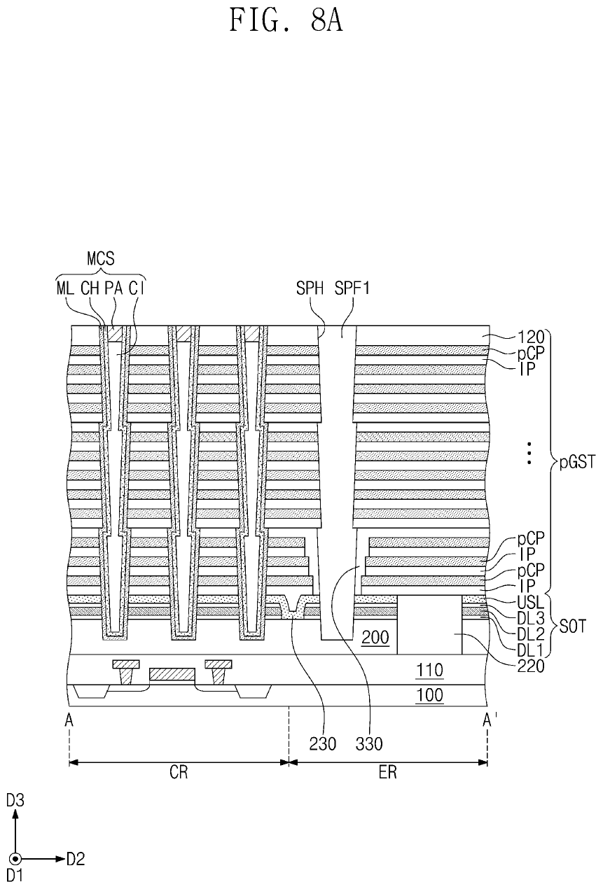

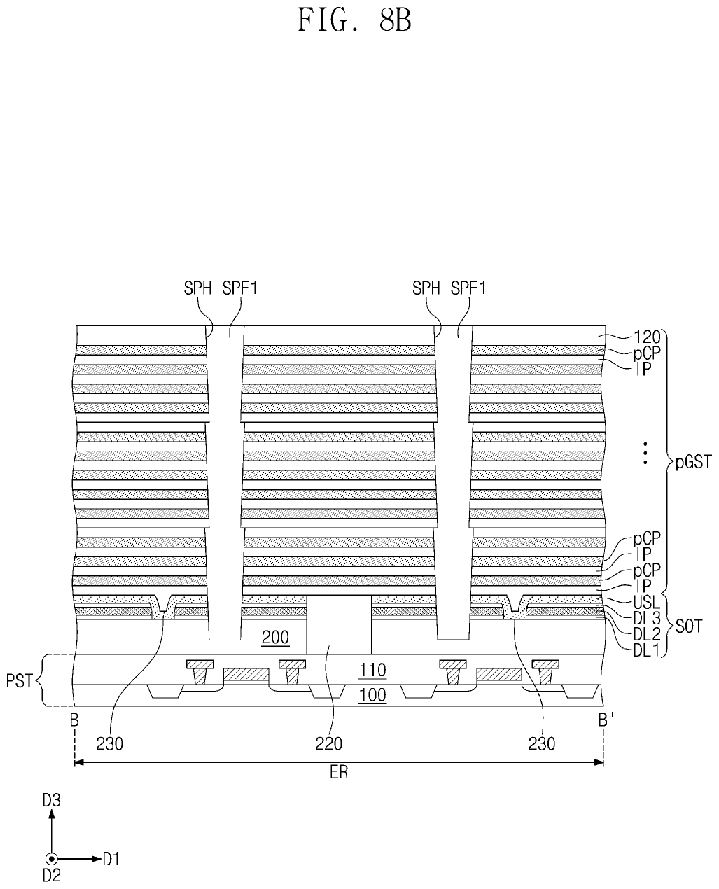

Referring to one or more example embodiments shown in FIGS. 8A and 8B, the memory channel structures MCS may be formed. The formation of the memory channel structures MCS may include removing the first channel filler CNF1. After the removal of the first channel filler CNF1, the memory layer ML, the channel layer CH, and the core insulating layer CI may be formed in the channel holes CNH. The pad PA may be formed on the core insulating layer CI. The supporting hole SPH may be in a state filled with the first supporting filler SPF1, during the above described process of forming the memory channel structures MCS.

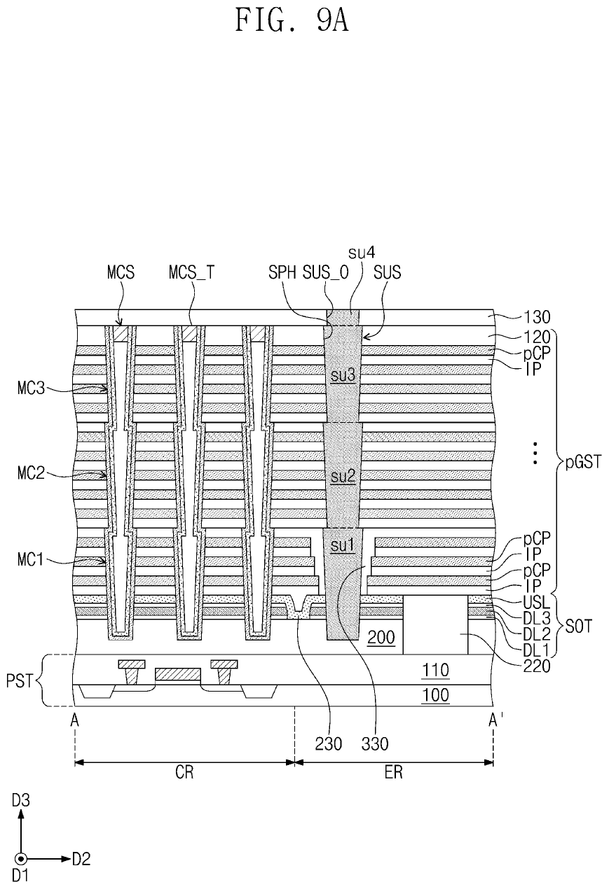

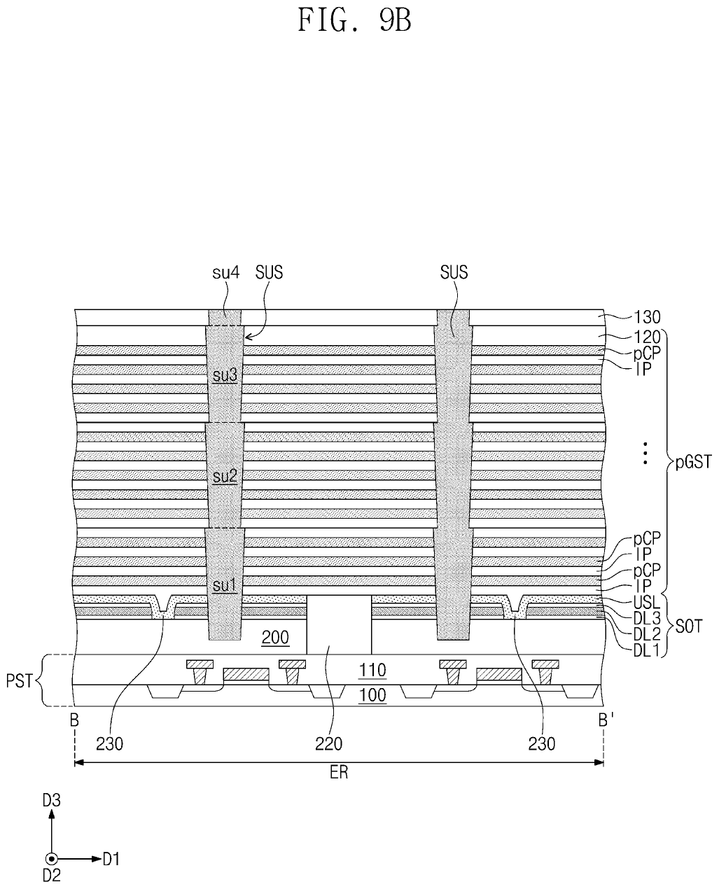

Referring to one or more example embodiments shown in FIGS. 9A and 9B, the supporting structures SUS may be formed in the extension region ER. The formation of the supporting structures SUS may include forming the first insulating layer 130 on the gate insulating layer 120. The first insulating layer 130 may be formed by depositing an insulating material on the gate insulating layer 120. The first insulating layer 130 may be formed on the preliminary gate stacking structure pGST and the memory channel structure MCS. After the formation of the first insulating layer 130, a supporting structure opening SUS_O may be formed in the first insulating layer 130 to expose the first supporting filler SPF1, and the first supporting filler SPF1, which is exposed through the supporting structure opening SUS_O, may be removed. After the removal of the first supporting filler SPF1, the supporting structure SUS may be formed by filling the supporting holes SPH with an insulating material. The insulating material may include, for example, but is not limited to, an oxide material oxide.

During the above described process of forming the supporting structures SUS, the top surface MCS_T of the memory channel structure MCS may be covered with the first insulating layer 130.

According to one or more example embodiments where the channel holes CNH are formed by the triple-stack forming process, the memory channel structure MCS may have the first channel portion MC1, the second channel portion MC2, and the third channel portion MC3. According to one or more example embodiments where the supporting holes SPH are formed by the triple-stack forming process, the supporting structures SUS may have the first supporting portion su1, the second supporting portion su2, the third supporting portion su3, and the fourth supporting portion su4. The fourth supporting portion su4 may be formed by filling the supporting structure opening SUS_O of the first insulating layer 130 with an insulating material.

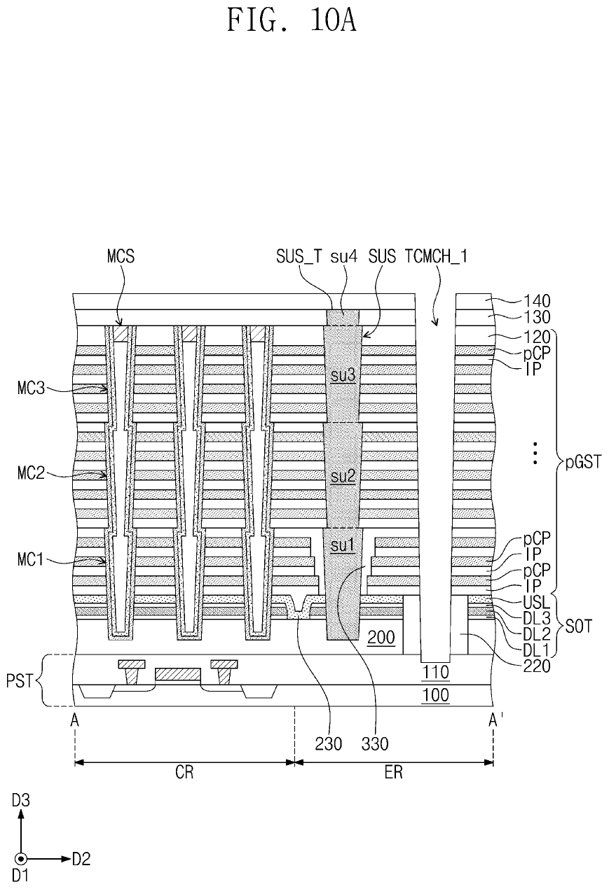

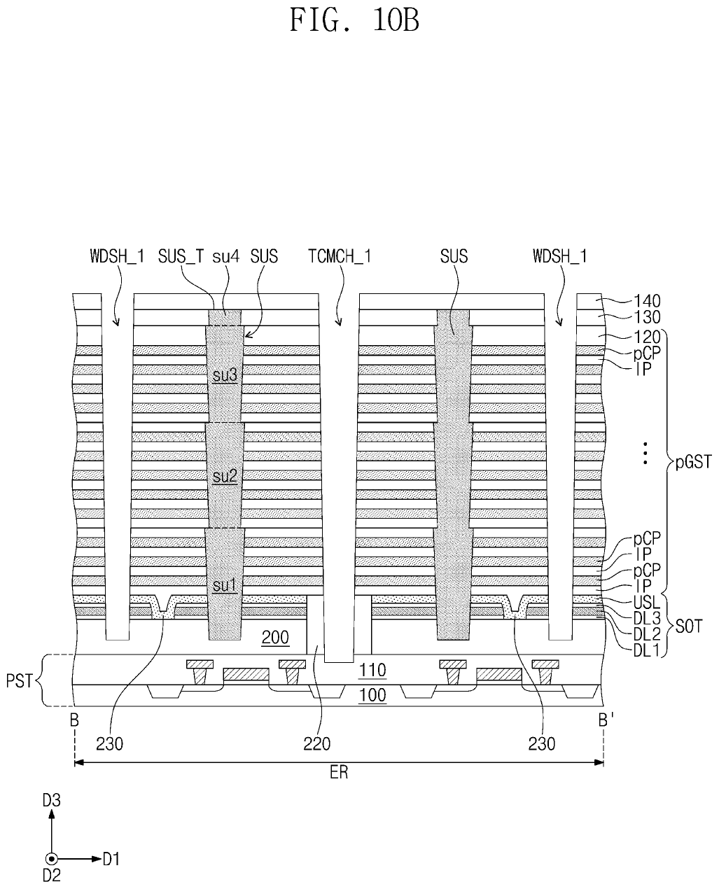

Referring to one or more example embodiments shown in FIGS. 10A and 10B, the second insulating layer 140 may be formed on the first insulating layer 130. The second insulating layer 140 may be formed by depositing an insulating material on the first insulating layer 130. Because the second insulating layer 140 is formed, a top surface SUS_T of the supporting structures SUS may be covered with an insulating material. After the formation of the second insulating layer 140, a first penetration plug hole TCMCH_1 may be formed to extend in the third direction D3 and to penetrate the second insulating layer 140, the first insulating layer 130, the preliminary gate stacking structure pGST, and the plug insulating layer 220. The first penetration plug hole TCMCH_1 may be formed to have a bottom that is located in the peripheral insulating layer 110.

First separation structure holes WDSH_1 may be formed to extend in the third direction D3 and to penetrate the second insulating layer 140, the first insulating layer 130, the preliminary gate stacking structure pGST, and the source structure SOT. The first separation structure holes WDSH_1 may be formed to have a bottom that is located in the semiconductor layer 200. The first separation structure holes WDSH_1 may be formed such that the source separation portion 230 is placed between the first separation structure hole WDSH_1 and the supporting structure SUS. The first separation structure holes WDSH_1 and the first penetration plug hole TCMCH_1 may be formed at the same time (e.g., using the same process). In one or more example embodiments, the first separation structure holes WDSH_1 and the first penetration plug hole TCMCH_1 may be formed by, for example, an atomic layer etching process.

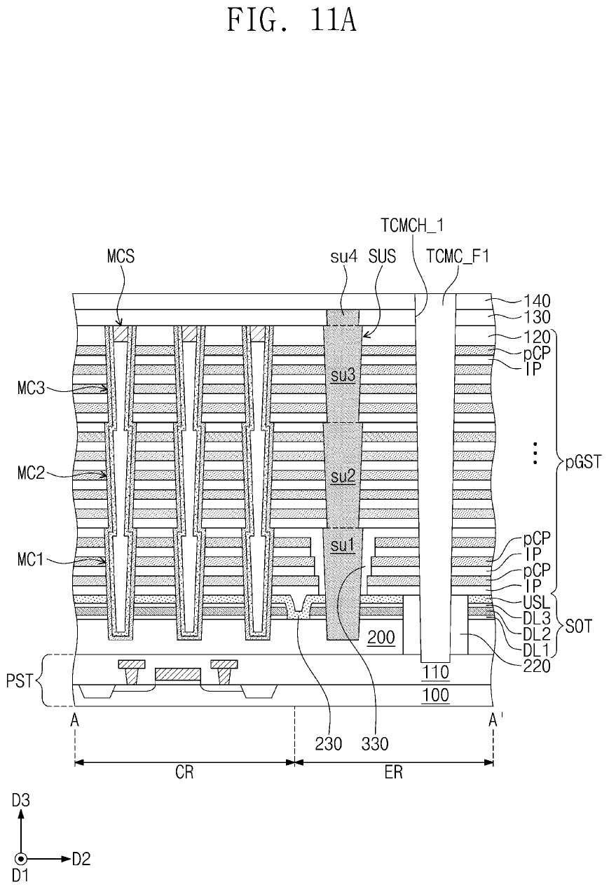

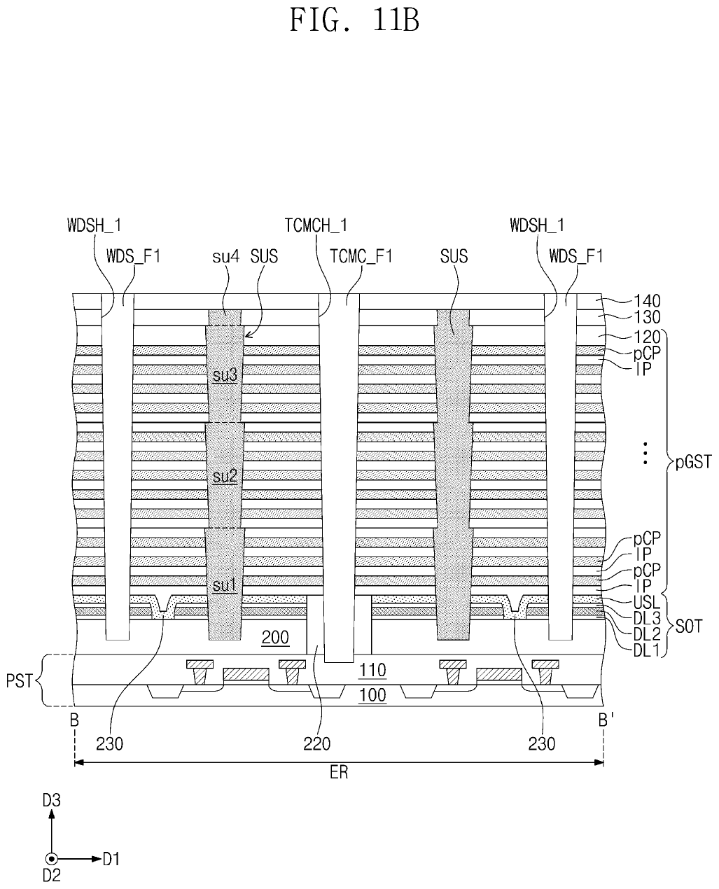

Referring to one or more example embodiments shown in FIGS. 11A and 11B, a first preliminary penetration plug TCMC_F1 may be formed in the first penetration plug hole TCMCH_1 by filling the first penetration plug hole TCMCH_1 with a second sacrificial material, and preliminary separation structures WDS_F1 may be formed in the first separation structure holes WDSH_1 by filling the first separation structure holes WDSH_1 with the second sacrificial material.

In one or more example embodiments, the second sacrificial material may be carbon. The first preliminary penetration plug TCMC_F1 and the preliminary separation structures WDS_F1 may cover side surfaces of the sacrificial patterns pCP, side surfaces of the insulating patterns IP, side surfaces of the upper source layer USL, side surfaces of the first, second and third dummy layers DL1, DL2, and DL3, and the semiconductor layer 200, which are exposed through the first penetration plug hole TCMCH_1 and the first separation structure holes WDSH_1.

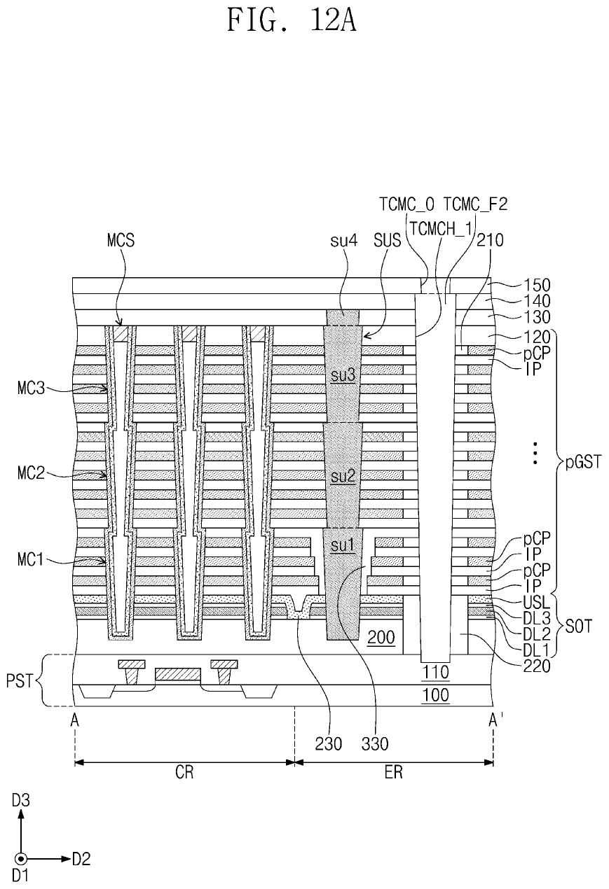

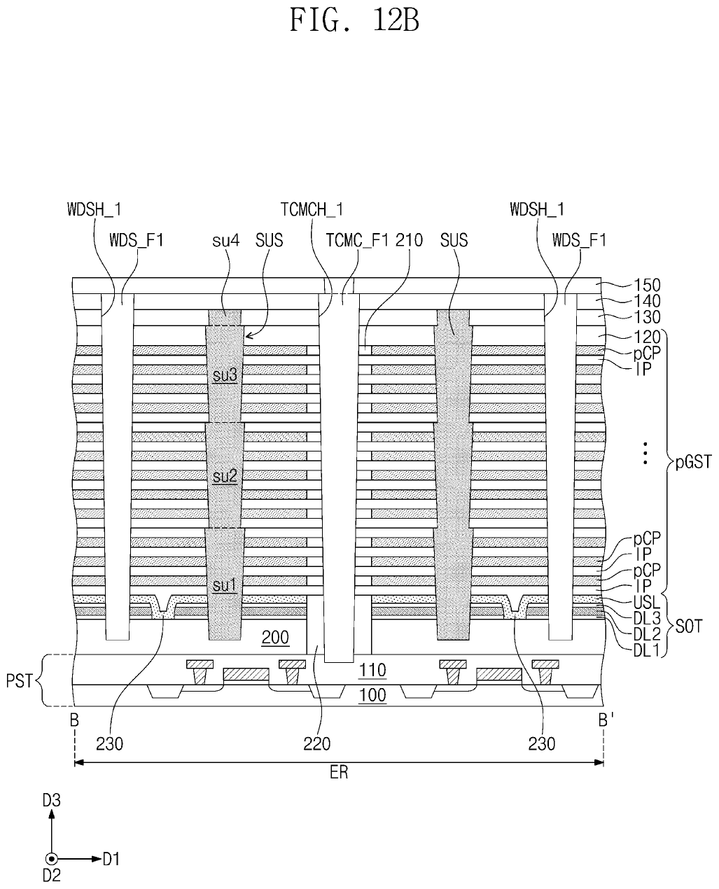

Referring to one or more example embodiments shown in FIGS. 12A and 12B, the third insulating layer 150 may be formed on the first preliminary penetration plug TCMC_F1, the preliminary separation structures WDS_F1, and the second insulating layer 140. The third insulating layer 150 may be formed by depositing an insulating material on the second insulating layer 140.

After the formation of the third insulating layer 150, a penetration plug opening TCMC_O may be formed in the third insulating layer 150 to expose the first preliminary penetration plug TCMC_F1, and then, the exposed first preliminary penetration plug TCMC_F1 may be removed through the penetration plug opening TCMC_O.

After the removal of the first preliminary penetration plug TCMC_F1, a portion of the sacrificial pattern pCP may be removed through the first penetration plug hole TCMCH_1, and then, the plug insulating patterns 210, which are in contact with the sacrificial patterns pCP, may be formed by depositing an insulating material in a region that is formed by removing the portion of the sacrificial pattern pCP. The insulating material may include, for example, but is not limited to, an oxide material oxide.

After the formation of the plug insulating patterns 210, a second preliminary penetration plug TCMC_F2 may be formed by filling the first penetration plug hole TCMCH_1 and the penetration plug opening TCMC_O with a third sacrificial material. In one or more example embodiments, the third sacrificial material may include, but is not limited to, carbon. Due to the plug insulating patterns 210, it may be possible to prevent the second preliminary penetration plug TCMC_F2 and the sacrificial patterns pCP from being directly connected to each other.

During the above described process of forming the second preliminary penetration plug TCMC_F2, a top surface of the preliminary separation structures WDS_F1 may be covered with the third insulating layer 150.

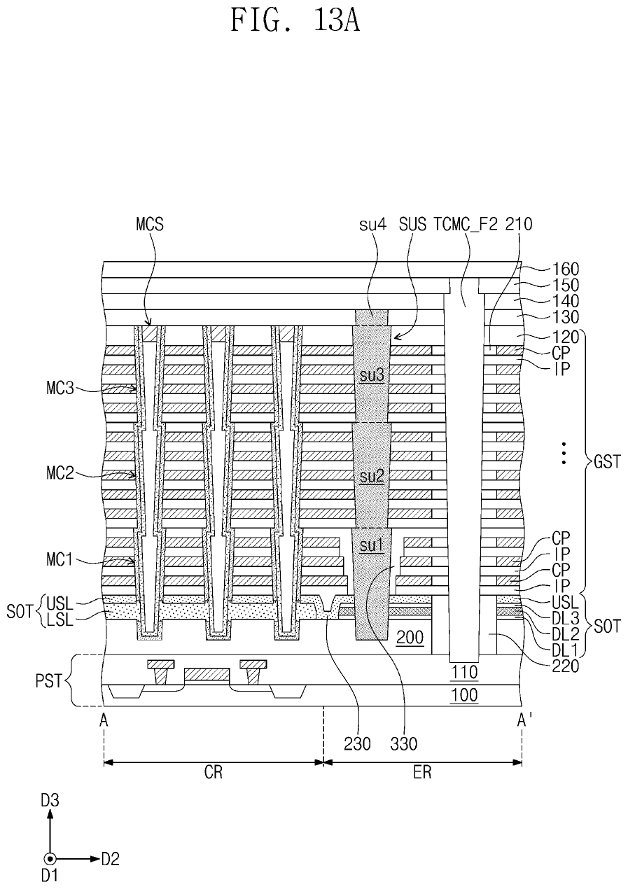

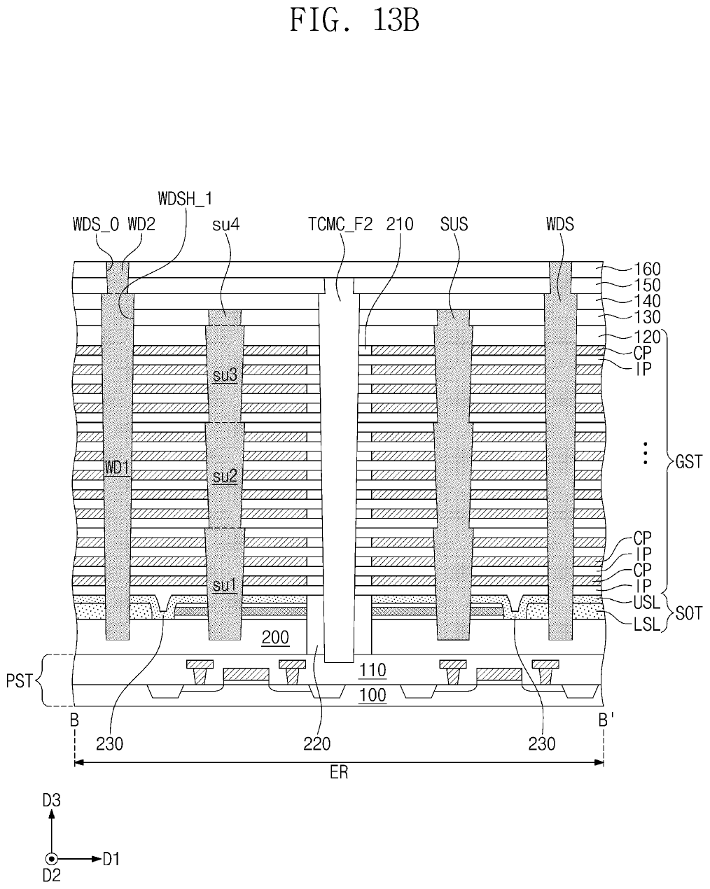

Referring to one or more example embodiments shown in FIGS. 13A and 13B, the fourth insulating layer 160 may be formed on the second preliminary penetration plug TCMC_F2 and the third insulating layer 150. The fourth insulating layer 160 may be formed by depositing an insulating material on the third insulating layer 150.

After the formation of the fourth insulating layer 160, a separation structure opening WDS_O may be formed in the third insulating layer 150 and the fourth insulating layer 160 to expose the preliminary separation structure WDS_F1, and then, the exposed preliminary separation structure WDS_F1 may be removed through the separation structure opening WDS_O.

After the removal of the preliminary separation structures WDS_F1, the first, second, and third dummy layers DL1, DL2, and DL3, which are exposed by the first separation structure holes WDSH_1, may be removed. The lower source layer LSL may be formed by depositing a conductive material in a region, which is formed by removing the first, second, and third dummy layers DL1, DL2, and DL3, through the first separation structure holes WDSH_1. The lower source layer LSL may be formed to be electrically connected to the memory channel structures MCS.

The sacrificial patterns pCP may be removed through the first separation structure holes WDSH_1. The conductive patterns CP may be formed by depositing a conductive material in regions that are formed by removing the sacrificial patterns pCP. As a result of the formation of the conductive patterns CP, the gate stacking structure GST including the conductive and insulating patterns CP and IP, which are alternately stacked on top of each other, may be formed.

After the formation of the lower source layer LSL and the conductive patterns CP, the separation structures WDS may be formed by filling the first separation structure holes WDSH_1 with an insulating material and filling openings of the third and fourth insulating layers 150 and 160 with an insulating material. The insulating material may include, for example, but is not limited to, an oxide material oxide. The separation structure WDS may include the first separation portion WD1, which is formed by filling the first separation structure hole WDSH_1 with the insulating material, and the second separation portion WD2, which is formed by filling the opening of the third and fourth insulating layers 150 and 160 with the insulating material.

During the above described process of forming the separation structure WDS, a top surface of the second preliminary penetration plug TCMC_F2 may be covered with the fourth insulating layer 160.

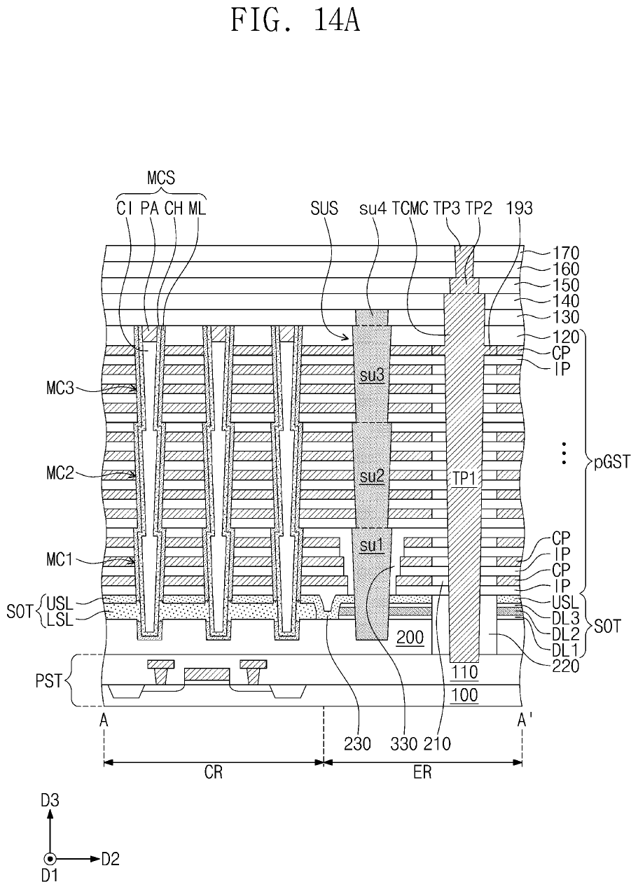

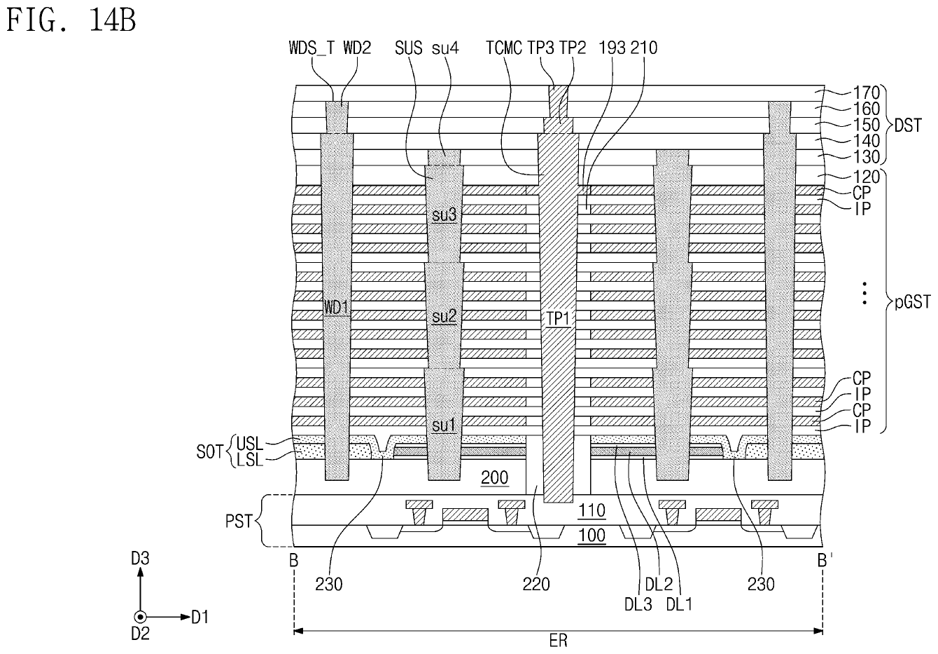

Referring to one or more example embodiments shown in FIGS. 14A and 14B, the fifth insulating layer 170 may be formed on the separation structures WDS and the fourth insulating layer 160. The fifth insulating layer 170 may be formed by depositing an insulating material on the fourth insulating layer 160. The first, second, third, fourth and fifth insulating layers 130, 140, 150, 160 and 170 may constitute the insulating structure DST. After the formation of the fifth insulating layer 170, openings may be formed in the fourth and fifth insulating layers 160 and 170 to expose the second preliminary penetration plugs TCMC_F2. The second preliminary penetration plugs TCMC_F2, which are exposed through the openings, may be removed.

After the removal of the second preliminary penetration plugs TCMC_F2, the penetration plug TCMC may be formed by filling the first penetration plug hole TCMCH_1 with a conductive material and filling the openings of the fourth and fifth insulating layers 160 and 170 with a conductive material. The conductive material may include, for example, but is not limited to, tungsten. The penetration plug TCMC may include the first plug portion TP1, which is formed by filling the first penetration plug hole TCMCH_1 with the conductive material, and the second plug portion TP2, which is formed by filling the opening of the fourth and fifth insulating layers 160 and 170 with a conductive material.

During the above described process of forming the penetration plug TCMC, a top surface WDS T of the separation structures WDS may be covered with the fifth insulating layer 170.

Referring back to FIGS. 5A, 5B, and 5C, the contact insulating layer 180 may be formed on the insulating structure DST including the first, second, third, fourth and fifth insulating layers 130, 140, 150, 160 and 170, and then, the line insulating layer 190 may be formed on the contact insulating layer 180.

The bit lines 300 may be formed in the line insulating layer 190. The bit lines 300 may be formed of, or include, at least one of conductive materials.

The bit line contact BC may be formed to penetrate the contact insulating layer 180 and the insulating structure DST and to be electrically connected to the pad PA of the memory channel structure MCS. The bit line contact BC may be formed to electrically connect the bit lines 300 to the memory channel structures MCS.

The plug conductive line 191 may be formed in the line insulating layer 190. The plug conductive line 191 may be formed of, or include, at least one of conductive materials. The plug contact 192 may be formed in the contact insulating layer 180 to penetrate the contact insulating layer 180 and to be electrically connected to the penetration plug TCMC. The bit line contact BC may be formed to have a length that is longer than the plug contact 192.

In a three-dimensional semiconductor device according to one or more example embodiments, a separation structure and a penetration plug may be formed at substantially the same time by a high aspect ratio etching process, and this may make it possible to reduce a failure of the semiconductor device and to improve the reliability characteristics of the semiconductor device.

While one or more example embodiments have been particularly shown and described above, it will be apparent to those of ordinary skill in the art that variations in form and detail may be made to one or more example embodiments without departing from the spirit and scope of the attached claims.

What is claimed is:

1. A three-dimensional semiconductor device comprising:
a source structure comprising a cell region and an extension region;
a gate stacking structure disposed on the source structure, the gate stacking structure comprising insulating patterns and conductive patterns, which are alternately stacked on each other;
an insulating structure disposed on the gate stacking structure, the insulating structure comprising a plurality of insulating layers;
a memory channel structure penetrating the gate stacking structure and electrically connected to the cell region;
a separation structure penetrating the gate stacking structure and extending from the cell region to the extension region; and
a penetration plug penetrating the gate stacking structure and the extension region,
wherein the penetration plug comprises:
a first plug portion penetrating the gate stacking structure; and
a second plug portion on the first plug portion,
wherein the separation structure comprises:
a first separation portion penetrating the gate stacking structure; and
a second separation portion on the first separation portion, and
wherein a top surface of the first plug portion and a top surface of the first separation portion are at a substantially same level.

2. The three-dimensional semiconductor device of claim 1, wherein the insulating structure comprises:
a first insulating layer;
a second insulating layer on the first insulating layer;
a third insulating layer on the second insulating layer;
a fourth insulating layer on the third insulating layer; and
a fifth insulating layer on the fourth insulating layer,
wherein a top surface of the memory channel structure and a bottom surface of the first insulating layer of the insulating structure are at a substantially same level,
wherein a top surface of the second separation portion and a top surface of the fourth insulating layer are at a substantially same level, and
wherein a top surface of the second plug portion of the penetration plug and a top surface of the third insulating layer are at a substantially same level.

3. The three-dimensional semiconductor device of claim 2, wherein the penetration plug further comprises a third plug portion on the second plug portion, and
wherein a top surface of the third plug portion and a top surface the fifth insulating layer are at a substantially same level.

4. The three-dimensional semiconductor device of claim 1, further comprising:
a contact insulating layer on the insulating structure;
a line insulating layer on the contact insulating layer;
a bit line contact penetrating the contact insulating layer and the insulating structure, and electrically connected to the memory channel structure; and
a plug contact penetrating the contact insulating layer, and electrically connected to the penetration plug, and
wherein a length of the bit line contact is greater than a length of the plug contact.

5. The three-dimensional semiconductor device of claim 1, further comprising plug insulating patterns between the penetration plug and the conductive patterns.

6. The three-dimensional semiconductor device of claim 1, wherein the separation structure comprises an insulating material.

7. The three-dimensional semiconductor device of claim 1, wherein a width of each of the first plug portion and the second plug portion decreases as a vertical level decreases.

8. The three-dimensional semiconductor device of claim 1, wherein a width of the first separation portion is greater than a width of the second separation portion.

9. A three-dimensional semiconductor device comprising:
a source structure comprising a cell region and an extension region;
a gate stacking structure disposed on the source structure, the gate stacking structure comprising insulating patterns and conductive patterns, which are alternately stacked on each other;
an insulating structure disposed on the gate stacking structure, the insulating structure comprising a plurality of insulating layers;
a memory channel structure penetrating the gate stacking structure and electrically connected to the cell region of the source structure;
a supporting structure penetrating the gate stacking structure and connected to the extension region; and
a penetration plug penetrating the gate stacking structure and the extension region,
wherein the penetration plug comprises:
a first plug portion penetrating the gate stacking structure; and
a second plug portion on the first plug portion,
wherein the supporting structure comprises:
a first supporting portion;
a second supporting portion on the first supporting portion;
a third supporting portion on the second supporting portion; and
a fourth supporting portion on the third supporting portion, and
wherein a top surface of the third supporting portion and a top surface of the memory channel structure are at a substantially same level.

10. The three-dimensional semiconductor device of claim 9, wherein the insulating structure comprises:
a first insulating layer;
a second insulating layer on the first insulating layer;
a third insulating layer on the second insulating layer;
a fourth insulating layer on the third insulating layer; and
a fifth insulating layer on the fourth insulating layer,
wherein the top surface of the memory channel structure and a bottom surface of the first insulating layer are at a substantially same level,
wherein a top surface of the fourth supporting portion and a bottom surface of the second insulating layer are at a substantially same level, and
wherein a top surface of the first plug portion and a top surface of the second insulating layer are at a substantially same level.

11. The three-dimensional semiconductor device of claim 9, wherein a width of the supporting structure is greater than a width of the memory channel structure.

12. The three-dimensional semiconductor device of claim 9, further comprising a first staircase insulating layer contacting the first supporting portion,
wherein the first staircase insulating layer is between the gate stacking structure and the first supporting portion.

13. The three-dimensional semiconductor device of claim 9, further comprising 16 supporting structures including the supporting structure, around the penetration plug, when the three-dimensional semiconductor device is viewed in a plan view.

14. The three-dimensional semiconductor device of claim 10, wherein the penetration plug further comprises a third plug portion on the second plug portion, and
wherein a top surface of the third plug portion and a top surface of the fifth insulating layer are at a substantially same level.

15. The three-dimensional semiconductor device of claim 9, further comprising:
a contact insulating layer on the insulating structure;
a line insulating layer on the contact insulating layer;
a bit line contact penetrating the contact insulating layer and the insulating structure and electrically connected to the memory channel structure; and
a plug contact penetrating the contact insulating layer and electrically connected to the penetration plug,
wherein a length of the bit line contact is greater than a length of the plug contact.

16. The three-dimensional semiconductor device of claim 9, further comprising plug insulating patterns between the penetration plug and the conductive patterns.

17. The three-dimensional semiconductor device of claim 9, wherein a width of each of the first plug portion and the second plug portion decreases as a vertical level decreases.

18. The three-dimensional semiconductor device of claim 9, wherein the supporting structure comprises an insulating material.

19. The three-dimensional semiconductor device of claim 9, wherein the memory channel structure comprises:
a first channel portion;
a second channel portion on the first channel portion; and
a third channel portion on the second channel portion;
wherein a top surface of the first channel portion a top surface of the first supporting portion are at a substantially same level,
wherein a top surface of the second channel portion and a top surface of the second supporting portion are at a substantially same level, and
wherein a top surface of the third channel portion and a top surface of the third supporting portion are at a substantially same level.

20. An electronic system comprising:
a substrate;
a semiconductor device on the substrate; and
a controller provided on the substrate and electrically connected to the semiconductor device,
wherein the semiconductor device comprises:
a peripheral circuit structure comprising a transistor;
a source structure on the peripheral circuit structure, the source structure comprising a cell region and an extension region;
a gate stacking structure disposed on the source structure, the gate stacking structure comprising insulating patterns and conductive patterns, which are alternately stacked on each other;
an insulating structure disposed on the gate stacking structure, the insulating structure comprising a plurality of insulating layers;
a memory channel structure penetrating the gate stacking structure and electrically connected to the cell region;
a separation structure penetrating the gate stacking structure and extending from the cell region to the extension region; and
a penetration plug penetrating the gate stacking structure and the extension region,
wherein the penetration plug comprises:
a first plug portion penetrating the gate stacking structure; and
a second plug portion on the first plug portion,
wherein the separation structure comprises:
a first separation portion penetrating the gate stacking structure; and
a second separation portion on the first separation portion, and
wherein a top surface of the first plug portion and a top surface of the first separation portion are at a substantially same level.
